(19) United States
(12) Patent Application Publication
(10) Pub. No.: US 2014/0054071 A1
(43) Pub. Date: Feb. 27, 2014

(54) FLEXIBLE PRINTED CIRCUIT BOARD AND TOUCH PANEL HAVING THE SAME

(71) Applicant: SAMSUNG ELECTRO-MECHANICS CO., LTD., Suwon (KR)

(72) Inventors: Young Jae Kim, Suwon (KR); Ha Yoon Song, Suwon (KR); Ho Joon Park, Suwon (KR)

(73) Assignee: SAMSUNG ELECTRO-MECHANICS CO., LTD., Suwon (KR)

(21) Appl. No.: 13/956,192

(22) Filed: Jul. 31, 2013

(30) Foreign Application Priority Data
Aug. 24, 2012 (KR) 10-2012-0093130

(51) Int. Cl. H05K 1/11; H05K 1/02

(52) U.S. Cl. CPC H05K 1/111; H05K 1/0277
USPC 174/254

(57) ABSTRACT

Disclosed herein are a flexible printed circuit board and a touch panel having the same. The touch panel includes a transparent substrate, a first electrode, a first wiring that is connected to the first electrode, a second electrode, a second wiring that is connected to the second electrode, and a flexible printed circuit board that includes a body portion, a plurality of pad portions that are formed so as to extend forward from an end of the body portion, and arranged side by side in a lateral direction while interposing a cut-open portion whose front side is open, and an extension portion that is formed so as to extend forward from an end of one of the plurality of pad portions.

### CROSS REFERENCE TO RELATED APPLICATION

This application claims the benefit of Korean Patent Application No. 10-2012-0093130, filed on Aug. 24, 2012, entitled “Flexible Printed Circuit Board and Touch Panel Having the Same”, which is hereby incorporated by reference in its entirety into this application.

### BACKGROUND OF THE INVENTION

1. Technical Field

The present invention relates to a flexible printed circuit board and a touch panel having the same.

2. Description of the Related Art

With the development of computers using digital technology, computer-assisted devices have been developed, and personal computers, portable transmission devices, information processing devices exclusive for individual, and the like perform a text and graphic process using a variety of input devices such as a keyboard, a mouse, and the like.

However, since the use of the computer has gradually widened with the rapid progress of an information society, there are difficulties in effectively driving products only using the keyboard and the mouse currently acting as an input device. Accordingly, there is a demand for an input device which has a simple operation and reduces an erroneous operation while allowing information input to be easily performed by anyone.

In addition, in input device-related technologies, the trend has changed toward high reliability, durability, innovativeness, design and processing-related technology, and the like in addition to satisfying general functions. Here, to achieve these purposes, as an input device through which information such as text, graphics, and the like can be input, a touch panel (touch screen) has been developed.

The touch panel is mounted on a display surface of a flat panel display device such as a digital organizer, a liquid crystal display (LCD), a plasma display panel (PDP), an electroluminescence (EL), or the like, and on a display surface of an image display device such as a cathode ray tube (CRT), and is used to allow a user to select their desired information while viewing the image display device.

Types of touch panels are classified as a resistive film type, a capacitance type, an electro-magnetic type, a surface acoustic wave (SAW) type, and an infrared type. The touch panels having these various types are applied to electronic products based on problems of signal amplification, resolution difference, the difficulty of design and processing technology, optical characteristics, electrical characteristics, mechanical characteristics, environment resistance characteristics, input characteristics, durability, and affordability, and a resistive film touch panel and a capacitance type touch panel are currently and widely used.

In a more detailed description of a touch panel structure according to the prior art, the touch panel generally includes a transparent substrate, an electrode that is formed on the transparent substrate for touch recognition, a wiring that is formed on the transparent substrate so as to be electrically connected with the electrode so that signals generated in the electrode are transmitted to the outside, and a flexible printed circuit board (FPCB) that is electrically connected to an end of the wiring and connected to the transparent substrate so as to transmit the signals transmitted through the wiring to a control unit.

The FPCB is connected to the transparent substrate in an adhesive manner, or the like, and as an example of the touch panel structure according to the prior art from which a specific connection structure between the FPCB and the transparent substrate can be known, a “touch panel sensor” disclosed in Korean Patent Laid-Open Publication No. 10-2011-0054369 may be given.

The FPCB of the touch panel structure according to the prior art may include a plurality of pad portions obtained in such a manner that an end of the FPCB connected to the transparent substrate is branched from a body of the FPCB, as disclosed in Korean Patent Laid-Open Publication No. 10-2011-0054369.

The reason why the above-described configuration is obtained is because the electrode formed on the transparent substrate is not only formed on one surface of the transparent substrate but on both surfaces of the transparent substrate or formed on either one surface of the transparent substrate or the other surface of a separate substrate stacked on the transparent substrate, and in this case, the FPCB should be connected to both surfaces of the transparent substrate or to each of the surfaces of the entire substrate on which the transparent substrate and the separate substrate are stacked.

In Korean Patent Laid-Open Publication No. 10-2011-0054369, there is disclosed the FPCB which includes two pad portions arranged side by side in a lateral direction in such a manner that the end of the FPCB is branched in two different directions. Other than this, the FPCB may have a structure in which three pad portions are arranged side by side so in a lateral direction as to be connected at one portion on one surface of both surfaces of the transparent substrate, and at two portions on the other surface thereof.

Meanwhile, since the structure of the touch panel according to the prior art includes the FPCB having the above-described structure, the touch panel has problems in performing a connection process of the transparent substrate and the FPCB.

Specifically, a manufacturing method of the touch panel according to the prior art includes a process in which at least two pad portions of the FPCB are branched in deviated directions (in a vertical direction) in order to connect the FPCB and the transparent substrate.

However, for automation of such a process, a separate device for rotating the pad portions of the FPCB in the branched directions should be provided, and therefore the manufacturing costs are increased.

In addition, a manual operation is unavoidably required for performing the above-described process even without a separate device, but in this case, a longer production lead time is required, and easiness of manufacturing is deteriorated.

### SUMMARY OF THE INVENTION

The present invention has been made in an effort to provide a flexible printed circuit board (FPCB) which improves a structure of a pad portion of the FPCB so that a connection process of a transparent substrate and the FPCB is easily performed through an automation process, and a touch panel having the same.

According to a preferred embodiment of the present invention, there is provided an FPCB including: a body portion; a plurality of pad portions that are formed so as to extend forward from an end of the body portion, and arranged side by side in a lateral direction while interposing a cut-open portion whose front side is open therebetween; and an extension portion that is formed so as to extend forward from an end of one of the plurality of pad portions.

The plurality of pad portions may include two pad portions that are arranged side by side in the lateral direction.

One of the two pad portions may be connected to one surface of a transparent substrate included in a touch panel, and the other thereof may be connected to the other surface of the transparent substrate.

The plurality of pad portions may include three pad portions that are arranged side by side in the lateral direction.

One of the three pad portions may be connected to one surface of a transparent substrate included in a touch panel, and the other two thereof may be connected to the other surface of the transparent substrate.

The pad portion connected to the one surface of the transparent substrate may be the pad portion that is positioned in the middle portion of the three pad portions.

A longitudinal direction of the cut-open portion may be formed in a front-and-rear direction.

An adhesion layer may be formed on the pad portion.

The adhesion layer may be an Anisotropic Conductive Film (ACF).

According to another preferred embodiment of the present invention, there is provided a touch panel including: a transparent substrate; a first electrode that is formed on one surface of the transparent substrate; a first wiring that is formed on the one surface of the transparent substrate so as to be connected to the first electrode; a second electrode that is formed on the other surface of the transparent substrate; a second wiring that is formed on the other surface of the transparent substrate so as to be connected to the second electrode; and a flexible printed circuit board that includes a body portion, a plurality of pad portions that are formed so as to extend forward from an end of the body portion, and arranged side by side in a lateral direction while interposing a cut-open portion whose front side is open, and an extension portion that is formed so as to extend forward from an end of one of the plurality of pad portions, wherein a part of the plurality of pad portions is electrically connected with the first wiring while being connected to one surface of the transparent substrate, and the remaining parts of the plurality of pad portions are electrically connected with the second wiring while being connected to the other surface of the transparent substrate.

The plurality of pad portions may include two pad portions that are arranged side by side in a lateral direction.

The plurality of pad portions may include three pad portions that are arranged side by side in a lateral direction.

The pad portion connected to the one surface of the transparent substrate may be the pad portion that is positioned in the middle portion of the three pad portions.

A longitudinal direction of the cut-open portion may be formed in a front-and-rear direction.

The pad portion may include an adhesion layer formed thereon to be adhered and connected to a connection portion of the transparent substrate.

The adhesion layer may be an Anisotropic Conductive Film (ACF).

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a perspective view showing a touch panel according to a first embodiment of the present invention;

FIG. 2 is a plan view showing a flexible printed circuit board (FPCB) shown in FIG. 1;

FIGS. 3 and 4 are cross-sectional views showing a connection process of an FPCB and a transparent substrate which are shown in FIG. 1;

FIG. 5 is a perspective view showing a touch panel according to a second embodiment of the present invention; and

FIG. 6 is a plan view showing an FPCB shown in FIG. 5.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

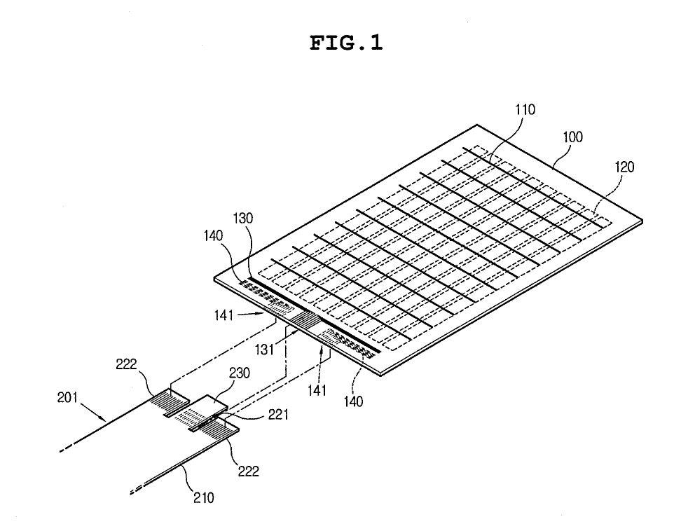

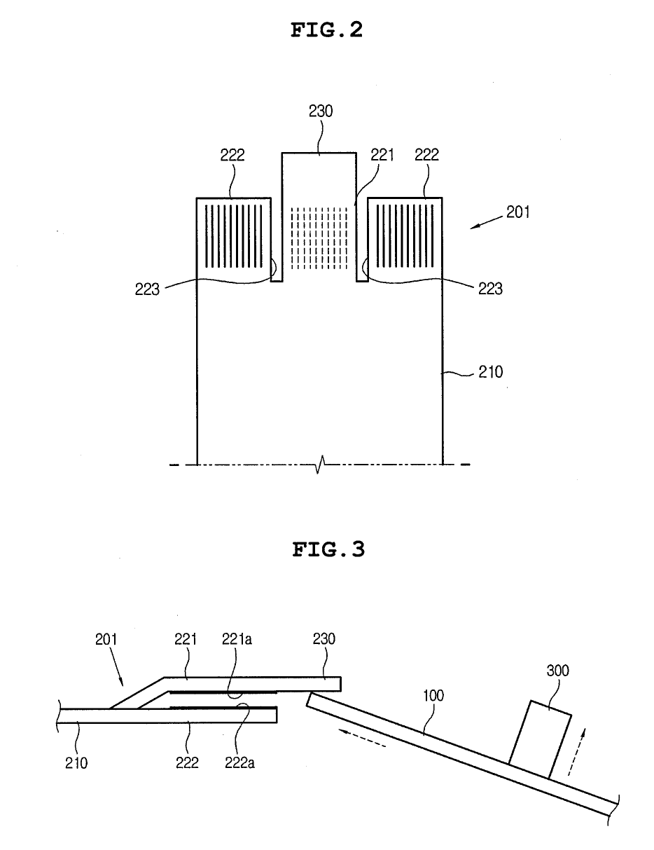

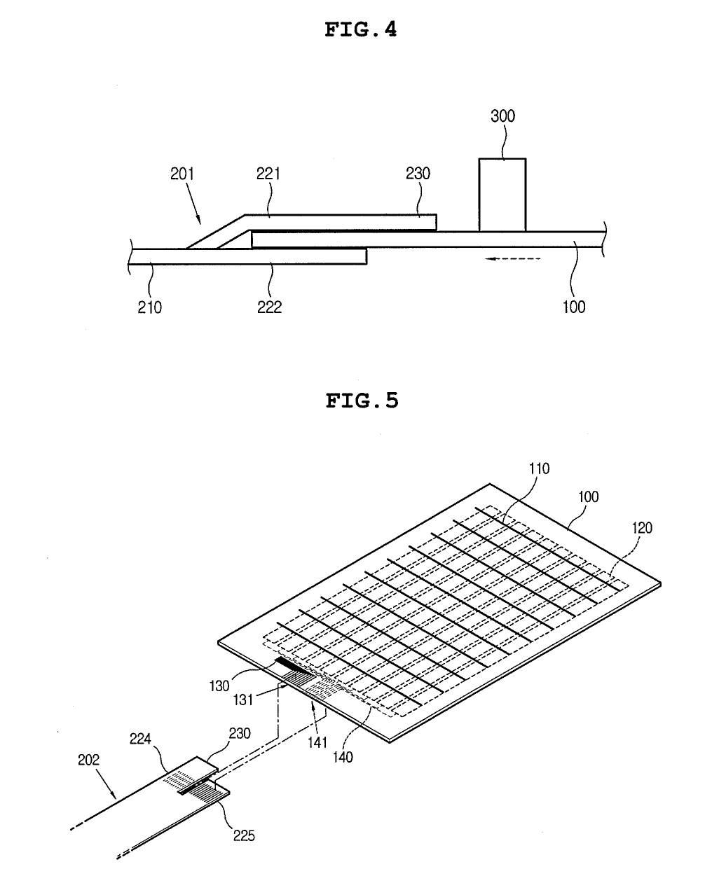

FIG. 1 is a perspective view showing a touch panel according to a first embodiment of the present invention, FIG. 2 is a plan view showing a flexible printed circuit board (FPCB) shown in FIG. 1, and FIGS. 3 and 4 are cross-sectional views showing a connection process of an FPCB and a transparent substrate which are shown in FIG. 1.

As shown in FIGS. 1 and 2, the touch panel according to the first embodiment of the present invention includes a transparent substrate 100, a first electrode 110 that is formed on one surface of the transparent substrate 100, a first wiring 130 that is formed on one surface of the transparent substrate 100 so as to be connected to the first electrode 110, a second electrode 120 that is formed on the other surface of the transparent substrate 100, a second wiring 140 that is formed on the other surface of the transparent substrate 100 so as to be connected to the second electrode 120, and an FPCB 201 that is connected to the transparent substrate 100 to thereby be electrically connected to the first wiring 130 and the second wiring 140.

The transparent substrate 100 provides a region in which the electrodes and the wirings are to be formed, which will be described below. The transparent substrate 100 should have supporting power capable of supporting the electrodes and the wirings, and transparency for enabling a user to recognize images provided from an image display device.

Considering the supporting power and the transparency, it is preferable that the transparent substrate 100 be made of polyethylene terephthalate (PET), polycarbonate (PC), polymethyl methacrylate (PMMA), polyethylene naphthalate (PEN), polyethersulfone (PES), cyclic olefin polymer (COC), a triacetylcellulose (TAC) film, a polyvinyl alcohol (PVA) film, a polyimide (PI) film, polystyrene (PS), “K” resin-contained biaxially oriented polystyrene (BOPS), glass, tempered glass, or the like, but is not necessarily limited thereto.

The electrode enables a controller (not shown) to recognize touch coordinates by generating signals at the time of touch of a user.

The signals generated in the electrode are transmitted to the controller (not shown) through the wiring and the FPCB 201, which will be described below.

The electrode is made of a material having electrical conductivity. For example, the electrode may be made of any one selected from copper (Cu), aluminum (Al), gold (Au), silver (Ag), titanium (Ti), palladium (Pd), and chrome (Cr) or a combination thereof, or made of a conductive polymer such as poly-3,4-ethylenedioxythiophene/polystyrenesulfonate (PEDOT/PSS), polyaniline, polyacetylene, or polyphenylenevinylene. Otherwise, the electrode may be made of a metal oxide such as indium-tin oxide, or the like.

In addition, the electrode may include the first electrode 110 formed on one surface of the transparent substrate 100 and the second electrode 120 formed on the other surface of the transparent substrate 100. In this instance, one of the first and second electrodes 110 and 120 may be used as a drive electrode and the other thereof may be used as a detection electrode.

The wiring may include the first wiring 130 that is electrically connected to the first electrode 110 and the second wiring 140 that is electrically connected to the second electrode 120. The first wiring 130 is formed on one surface of the transparent substrate 100 while being connected to the first electrode 110, and the second wiring 140 is formed on the other surface of the transparent substrate 100 while being connected to the second electrode 120.

A distal end of the first wiring 130 may be positioned at an end portion of the one surface of the transparent substrate 100. As shown in FIG. 1, the distal end of the first wiring 130 may be positioned in, for example, a rear end portion of the one surface of the transparent substrate 100, and may be a connection portion 131 that is connected to the FPCB 201, which will be described below.

In the same manner, a distal end of the second wiring 140 may be positioned at a rear end portion of the other surface of the transparent substrate 100, and may be a connection portion 141 that is connected to the FPCBs 201 and 202.

In an example shown in FIG. 1, a single connection portion 131 is formed on the one surface of the transparent substrate 100, and two connection portions 141 are formed on the other surface of the transparent substrate 100.

The FPCB 201 is connected to the connection portions 131 and 141 while being connected to the transparent substrate 100 to thereby be electrically connected with the first and second wirings 130 and 140.

As a specific example, the FPCB 201 may include a body portion 210, pad portions 221 and 222, and an extension portion 230, as shown in FIGS. 1 and 2.

The body portion 210 is a body of the FPCB 201, and the pad portions 221 and 222 are formed at an end portion of the body portion 210. The pad portions 221 and 222 are electrically connected to the above-described connection portions 131 and 141, and when a single connection portion 131 is formed on the one surface of the transparent substrate 100 and two connection portions 141 are formed on the other surface thereof as described above, three pad portions 221 and 222 of the FPCB 201 are formed so as to correspond to such connection portions 131 and 141.

In this instance, the pad portions 221 and 222 may be arranged side by side in a lateral direction while interposing a cut-open portion 223 whose longitudinal direction is formed in a front-and-rear direction. In the present embodiment, since the pad portion includes three pad portions 221 and 222, two cut-open portions 223 are formed between the three pad portions 221 and 222, and a front side of each cut-open portion 223 is open. Since the cut-open portion 223 is formed between the three pad portions 221 and 222, the three pad portions 221 and 222 may be freely rotated in a vertical direction without any interference of the adjacent pad portion.

When a part of the plurality of pad portions is rotated upward and the remaining parts thereof are rotated downward, a space to which the transparent substrate 100 is inserted is formed between the pad portions. The transparent substrate 100 is inserted into the space, and then a lower surface of the pad portion rotated upward is connected to the connection portion 131 formed on the one surface of the transparent substrate 100 and an upper surface of the pad portion rotated downward is connected to the connection portion 141 formed on the other surface of the transparent substrate 100, and therefore the FPCB 201 may be electrically connected with the first wiring 130 and the second wiring 140.

In this instance, when the plurality of pad portions of the FPCB 201 are all formed to have the same length, a process in which the plurality of pad portions are rotated in deviated directions (vertical direction) to be branched is not easily performed. For this process, a separate device for rotating each of the pad portions is required, or a manual operation by an operator is required. When the separate device is provided for the above-described process, manufacturing costs of the touch panel are increased. When the above-described process is performed by manually, an operator has to spread the pad portions while holding each of the pad portions, and therefore easiness of manufacturing is significantly deteriorated.

In order to overcome this problem, the FPCB 201 according to the present embodiment includes the extension portion 230 that is formed so as to extend from the pad portion.

The extension portion 230 is formed so as to extend forward from a front end of one of the plurality of the pad portions 221 and 222. Due to the formed extension portion 230, the pad portion 221 in which the extension portion 230 is formed has a longer length than that of the pad portion 222 in which the extension portion 230 is not formed. In FIGS. 1 and 2, as an example, the extension portion 230 is formed in the pad portion 221 that is disposed in the middle portion of the three pad portions 221 and 222, but the invention is not limited thereto. Obviously, the extension portion 230 may be formed in all the pad portions 222 disposed on the left and right sides, or formed in one of them.

A process of mutually connecting the transparent substrate 100 and the FPCB 201 is easily performed due to the formed extension portion 230, and such a process will be described with reference to FIGS. 3 and 4 as follow.

As described above, in an example in which the extension portion 230 is formed in the middle pad portion 221 (hereinafter, referred to as a “first pad portion”) of the three pad portions 221 and 222, in a case in which the first pad portion 221 is connected to the connection portion 131 of the one surface of the transparent substrate 100 and the remaining pad portion 222 (hereinafter, referred to as a “second pad portion”) is connected to the connection portion 141 of the other surface of the transparent substrate 100, the extension portion 230 and the first pad portion 221 are rotated upward when a rear end portion (a left end portion of the transparent substrate 100 based on FIG. 3) of the transparent substrate 100 is moved upward in a state in which a rear end portion of the transparent substrate 100 is brought into contact with a lower surface of the extension portion 230 as shown in FIG. 3. In this instance, when a space is formed between the first pad portion 221 and the second pad portion 222, the rear end portion of the transparent substrate 100 may be inserted into the space as shown in FIG. 4. The transparent substrate 100 is inserted into the space between the first pad portion 221 and the second pad portion 222, and then a lower surface of the first pad portion 221 may be connected to the connection portion 131 formed on the one surface of the transparent substrate 100, and an upper surface of the second pad portion 222 may be connected to the connection portion 141 formed on the other surface of the transparent substrate 100. In this instance, adhesion layers 221a and 222a may be respectively formed on the lower surface of the first pad portion 221 and the upper surface of the second pad portion 222, and the first and second pad portions 221 and 222 may be adhered and connected to the connection portions 131 and 141, so that the first pad portion 221 and the second pad portion 222 are fixed in a state of being connected to the connection portions 131 and 141. Here, the adhesion layers 221a and 222a may be formed of, for example, an Anisotropic Conductive Film (ACF).

In the touch panel according to the present embodiment, since the connection process of the FPCB 201 and the transparent substrate 100 is performed by a simple method of pushing up the extension portion 230 by the transparent substrate 100 as described above, the connection process may be easily performed in a case of a manual operation.

In addition, since the connection process may be performed using the existing holder 300 for moving the transparent substrate 100 as shown in FIGS. 3 and 4, the connection process may be performed by an automation process without relying on a manual operation and a separate device.

Hereinafter, a touch panel according to a second embodiment of the present invention will be described with reference to the accompanying drawings.

FIG. 5 is a perspective view showing a touch panel according to a second embodiment of the present invention, and

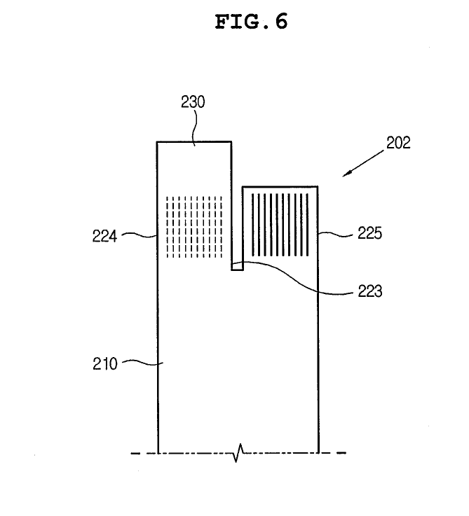

FIG. 6 is a plan view showing an FPCB shown in FIG. 5.

The touch panel according to the present embodiment has a different structure of an FPCB as compared to the structure of the touch panel according to the first embodiment. Hereinafter, an FPCB 202 according to the present embodiment will be described in detail.

The pad portion of the FPCB 202 according to the embodiment includes two pad portions 224 and 225, unlike the pad portion according to the first embodiment.

In the first embodiment, an example in which a single connection portion 131 is formed on the one surface of the transparent substrate 100 and two connection portions 141 are formed on the other surface thereof, so that three pad portions 221 and 222 are formed on the FPCB 201 has been shown, but the invention is not limited thereto.

As shown in FIG. 5, a single connection portion 131 may be formed on the one surface of the transparent substrate 100, and a single connection portion 141 may be formed on the other surface thereof. In this case, two pad portions 224 and 225 may be formed on the FPCB 202.

The two pad portions 224 and 225 may be arranged side by side in a lateral direction while interposing a cut-open portion 223, one of the two pad portions 224 and 225 may be connected to the connection portion 131 formed on the one surface of the transparent substrate 100, and the other thereof may be connected to the connection portion 131 formed on the other surface of the transparent substrate 100.

In this instance, the extension portion 230 may be formed in one of the two pad portions 224 and 225, and as shown in drawing, the extension portion 230 is formed in the left pad portion 224.

In the present embodiment like the first embodiment, a space between the pad portions 224 and 225 may be formed by pushing up the extension portion 230 by the rear end portion of the transparent substrate 100 when the extension portion 230 is formed in the pad portion 224, and the pad portions 224 and 225 may be connected to the connection portions 131 and 141 by inserting the rear end portion of the transparent substrate 100 into the space.

As set forth above, according to the embodiments of the present invention, the extension portion is formed in the pad portion of the FPCB, and therefore a space into which the transparent substrate is inserted may be ensured between the pad portions by a simple process of pushing up the extension portion.

Accordingly, a connection process of the transparent substrate and the FPCB may be performed through an automation process only using a device of moving the transparent substrate without a separate device of spreading the pad portion.

In addition, since an operator may easily hold and rotate the protruded extension portion, the above-described process may be significantly performed easily even manually.

Although the embodiments of the present invention have been disclosed for illustrative purposes, it will be appreciated that the present invention is not limited thereto, and those skilled in to the art will appreciate that various modifications, additions and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A flexible printed circuit board comprising:
a body portion;
a plurality of pad portions that are formed so as to extend forward from an end of the body portion, and arranged side by side in a lateral direction while interposing a cut-open portion whose front side is open therebetween; and
an extension portion that is formed so as to extend forward from an end of one of the plurality of pad portions.

2. The flexible printed circuit board as set forth in claim 1, wherein the plurality of pad portions include two pad portions that are arranged side by side in the lateral direction.

3. The flexible printed circuit board as set forth in claim 2, wherein one of the two pad portions is connected to one surface of a transparent substrate included in a touch panel, and the other thereof is connected to the other surface of the transparent substrate.

4. The flexible printed circuit board as set forth in claim 1, wherein the plurality of pad portions include three pad portions that are arranged side by side in the lateral direction.

5. The flexible printed circuit board as set forth in claim 4, wherein one of the three pad portions is connected to one surface of a transparent substrate included in a touch panel, and the other two thereof are connected to the other surface of the transparent substrate.

6. The flexible printed circuit board as set forth in claim 5, wherein the pad portion connected to the one surface of the transparent substrate is the pad portion that is positioned in the middle portion of the three pad portions.

7. The flexible printed circuit board as set forth in claim 1, wherein a longitudinal direction of the cut-open portion is formed in a front-and-rear direction.

8. The flexible printed circuit board as set forth in claim 1, wherein an adhesion layer is formed on the pad portion.

9. The flexible printed circuit board as set forth in claim 8, wherein the adhesion layer is an Anisotropic Conductive Film (ACF).

10. A touch panel comprising:
a transparent substrate;
a first electrode that is formed on one surface of the transparent substrate;
a first wiring that is formed on the one surface of the transparent substrate so as to be connected to the first electrode;
a second electrode that is formed on the other surface of the transparent substrate;
a second wiring that is formed on the other surface of the transparent substrate so as to be connected to the second electrode; and
a flexible printed circuit board that includes a body portion, a plurality of pad portions that are formed so as to extend forward from an end of the body portion, and arranged side by side in a lateral direction while interposing a cut-open portion whose front side is open therebetween, and an extension portion that is formed so as to extend forward from an end of one of the plurality of pad portions,
wherein a part of the plurality of pad portions is electrically connected with the first wiring while being connected to one surface of the transparent substrate, and the remaining parts of the plurality of pad portions are electrically connected with the second wiring while being connected to the other surface of the transparent substrate.

11. The touch panel as set forth in claim 10, wherein the plurality of pad portions include two pad portions that are arranged side by side in a lateral direction.

12. The touch panel as set forth in claim 10, wherein the plurality of pad portions include three pad portions that are arranged side by side in a lateral direction.

13. The touch panel as set forth in claim 12, wherein the pad portion connected to the one surface of the transparent substrate is the pad portion that is positioned in the middle portion of the three pad portions.

14. The touch panel as set forth in claim 10, wherein a longitudinal direction of the cut-open portion is formed in a front-and-rear direction.

15. The touch panel as set forth in claim 10, wherein the pad portion includes an adhesion layer formed thereon to be adhered and connected to a connection portion of the transparent substrate.

16. The touch panel as set forth in claim 15, wherein the adhesion layer is an Anisotropic Conductive Film (ACF).
